(19) United States
(12) Patent Application Publication
(10) Pub. No.: US 2026/0249590 A1
(43) Pub. Date: Aug. 27, 2026

(54) COMPOSITE MATERIAL, HEAT SPREADER, AND SEMICONDUCTOR PACKAGE

(71) Applicants: SUMITOMO ELECTRIC INDUSTRIES, LTD., Osaka (JP); A.L.M.T. Corp., Tokyo (JP)

(72) Inventors: Keita SASAKI, Osaka (JP); Toru MAEDA, Osaka (JP); Daisuke KONDO, Osaka (JP); Masayuki ITO, Yamagata (JP); Shin-ichi YAMAGATA, Yamagata (JP)

(73) Assignees: SUMITOMO ELECTRIC INDUSTRIES, LTD., Osaka (JP); A.L.M.T. Corp., Tokyo (JP)

(21) Appl. No.: 18/995,427

(22) PCT Filed: Jul. 13, 2023
(86) PCT No.: PCT/JP2023/025926

§ 371 Date: Jan. 16, 2025

(30) Foreign Application Priority Data
Aug. 4, 2022 (JP) 2022-124936

(51) Int. Cl. B32B 15/01; B32B 3/26; H10W 40/20; H10W 40/25

(52) U.S. Cl. CPC B32B 15/01; B32B 3/266; H10W 40/242; H10W 40/255

(57) ABSTRACT

A composite material is in a form of a plate provided with a first surface and a second surface which is a surface opposite to the first surface. The composite material includes a plurality of first layers and at least one second layer. The first surface and the second surface form end surfaces in a thickness direction of the composite material. The first layer and the second layer are alternately layered along the thickness direction such that the first layer is located at the first surface and the second surface. The first layer is a layer of a metallic material mainly composed of copper. The second layer includes a molybdenum plate and a copper filler. The molybdenum plate is provided with a plurality of openings that pass through the molybdenum plate along the thickness direction. The copper filler is arranged in the inside of the openings.

### TECHNICAL FIELD

The present disclosure relates to a composite material, a heat spreader, and a semiconductor package. The present application claims priority to Japanese Patent Application No. 2022-124936 filed on Aug. 4, 2022, the entire contents of which are herein incorporated by reference.

### BACKGROUND ART

For example, WO2022/030197 (PTL 1) describes a composite material in a form of a plate. The composite material described in PTL 1 is provided with a first surface and a second surface which is a surface opposite to the first surface. The first surface and the second surface form end surfaces in a thickness direction of the composite material (which will be referred to as a “thickness direction” below) described in PTL 1.

The composite material described in PTL 1 includes a plurality of first layers and a plurality of second layers. The first layer and the second layer are stacked alternately along the thickness direction such that the first layer is located at the first surface and the second surface. The first layer is a layer of a metallic material containing copper as a main component. The second layer includes a molybdenum plate and a copper filler. The molybdenum plate is provided with a plurality of openings. The openings pass through the molybdenum plate along the thickness direction. The openings are circular in a plan view and arranged in lattice of squares in the plan view. The copper filler is arranged in the inside of the openings.

### CITATION LIST

### Patent Literature

PTL 1: WO2022/030197

### SUMMARY OF INVENTION

A composite material in the present disclosure is in a form of a plate provided with a first surface and a second surface, the second surface being a surface opposite to the first surface. The composite material includes a plurality of first layers and at least one second layer. The first surface and the second surface form end surfaces in a thickness direction of the composite material. The first layer and the second layer are alternately layered along the thickness direction such that the first layer is located at the first surface and the second surface. The first layer is a layer of a metallic material mainly composed of copper. The second layer includes a molybdenum plate and a copper filler. The molybdenum plate is provided with a plurality of openings that pass through the molybdenum plate along the thickness direction. The copper filler is arranged in the inside of the openings. In a cross-sectional view orthogonal to the thickness direction, the openings are aligned in lattice arrangement. In the cross-sectional view orthogonal to the thickness direction, the openings each have a first width in a row direction of the lattice arrangement and a second width in a column direction of the lattice arrangement orthogonal to the row direction. The first width is larger than 350 μm. A value calculated by dividing the second width by the first width is not smaller than one and not larger than two. In the cross-sectional view orthogonal to the thickness direction, the molybdenum plate includes a portion that is continuous without interfering with the openings along a first direction and a portion that is continuous without interfering with the openings along a second direction different from the first direction. An angle formed between the first direction and the second direction is not smaller than 47° and not larger than 90°.

### BRIEF DESCRIPTION OF DRAWINGS

FIG. 1 is a perspective view of a composite material 10.

FIG. 2 is a cross-sectional view along II-II in FIG. 1.

FIG. 3 is a cross-sectional view along III-III in FIG. 2.

FIG. 4A is a first illustrative diagram of a procedure of making a measurement sample for measuring a thermal conductivity in a thickness direction of composite material 10.

FIG. 4B is a second illustrative diagram of the procedure of making the measurement sample for measuring the thermal conductivity in the thickness direction of composite material 10.

FIG. 4C is a third illustrative diagram of the procedure of making the measurement sample for measuring the thermal conductivity in the thickness direction of composite material 10.

FIG. 5 is a diagram of a process for manufacturing composite material 10.

FIG. 6 is an exploded perspective view of a semiconductor package 100.

### DETAILED DESCRIPTION

### Problem to be Solved by the Present Disclosure

In the composite material described in PTL 1, an aperture of the opening is small and there is a room for improvement in thermal conductivity in the thickness direction of the second layer. When the aperture of the opening is made larger for improvement in thermal conductivity in the thickness direction of the second layer in the composite material described in PTL 1, a distance between two adjacent openings becomes shorter and the molybdenum plate may break between the two adjacent openings. In order to avoid such break, the openings may be arranged, for example, as being staggered. Staggered arrangement of the openings, however, may lead to greater anisotropy of a coefficient of linear expansion in a plane orthogonal to the thickness direction.

The present disclosure was made in view of problems of the conventional art as above. More specifically, the present disclosure provides a composite member that can achieve less anisotropy of a coefficient of linear expansion in a plane orthogonal to a thickness direction.

### Effect of the Present Disclosure

According to a composite material in the present disclosure, anisotropy of the coefficient of linear expansion in the plane orthogonal to the thickness direction can be less.

### DESCRIPTION OF EMBODIMENT IN THE PRESENT DISCLOSURE

Embodiments of the present disclosure will initially be listed and described.

(1) A composite material according to an embodiment is in a form of a plate provided with a first surface and a second surface, the second surface being a surface opposite to the first surface. The composite material includes a plurality of first layers and at least one second layer. The first surface and the second surface form end surfaces in a thickness direction of the composite material. The first layer and the second layer are alternately layered along the thickness direction such that the first layer is located at the first surface and the second surface. The first layer is a layer of a metallic material mainly composed of copper. The second layer includes a molybdenum plate and a copper filler. The molybdenum plate is provided with a plurality of openings that pass through the molybdenum plate along the thickness direction. The copper filler is arranged in the inside of the openings. In a cross-sectional view orthogonal to the thickness direction, the openings are aligned in lattice arrangement. In the cross-sectional view orthogonal to the thickness direction, the openings each have a first width in a row direction of the lattice arrangement and a second width in a column direction of the lattice arrangement orthogonal to the row direction. The first width is larger than 350 μm. A value calculated by dividing the second width by the first width is not smaller than one and not larger than two. In the cross-sectional view orthogonal to the thickness direction, the molybdenum plate includes a portion that is continuous without interfering with the openings along a first direction and a portion that is continuous without interfering with the openings along a second direction different from the first direction. An angle formed between the first direction and the second direction is not smaller than 47° and not larger than 90°.

According to the composite material in (1), anisotropy of a coefficient of linear expansion in a plane orthogonal to the thickness direction can be less.

(2) In the composite material in (1), the angle formed between the first direction and the second direction may be smaller than 90°.

(3) In the composite material in (1) or (2), in the cross-sectional view orthogonal to the thickness direction, the number of the openings per 1 mm² may be smaller than three.

(4) In the composite material in (1) or (2), in the cross-sectional view orthogonal to the thickness direction, the number of the openings per 1 mm² may be smaller than two.

(5) In the composite material in (1) to (4), in the cross-sectional view orthogonal to the thickness direction, an aperture ratio of the molybdenum plate may be not lower than 20 percent.

(6) In the composite material in (1) to (5), a volume ratio of molybdenum in the composite material may be not higher than 25 percent.

(7) In the composite material in (1) to (5), a volume ratio of molybdenum in the composite material may be not lower than 15 percent. According to the composite material in (7), the coefficient of linear expansion can be made smaller.

(8) In the composite material in (1) to (5), a volume ratio of molybdenum in the composite material may be lower than 15 percent. According to the composite material in (8), a thermal conductivity can be made higher.

(9) In the composite material in (1) to (8), a total of the number of first layers and the number of second layers may be set to five. The composite material may have a thickness not larger than 1.5 mm. The second layer may have a thickness not larger than 0.3 mm.

(10) In the composite material in (1) to (9), a value calculated by dividing a coefficient of linear expansion in the row direction in change of a temperature from room temperature to 800° C. by a coefficient of linear expansion in the column direction in change in temperature from room temperature to 800° C. may be not larger than 1.5.

(11) In the composite material in (1) to (10), a pitch between the openings adjacent in the column direction may be larger than a pitch between the openings adjacent in the row direction.

(12) A heat spreader according to an embodiment includes the composite material according to (1) to (11). The first surface forms a surface of contact with a heat generation source.

(13) A semiconductor package according to an embodiment includes the composite material according to (1) to (11) and a semiconductor element. The semiconductor element is arranged on the first surface.

(14) The semiconductor package in (13) may further include a case member made of a ceramic material. The case member may be arranged on the first surface as surrounding the semiconductor element.

### Details of Embodiment in the Present Disclosure

Details of an embodiment of the present disclosure will now be described with reference to the drawings. The same or corresponding elements in the drawings below have the same reference characters allotted and redundant description will not be repeated. A composite material according to the embodiment is referred to as a composite material 10. A semiconductor package according to the embodiment is referred to as a semiconductor package 100.

### (Construction of Composite Material 10)

A construction of composite material 10 will be described below.

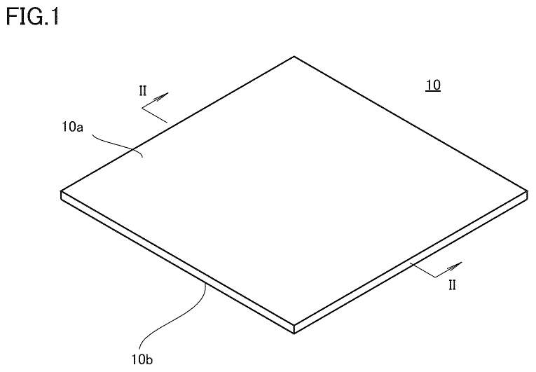

FIG. 1 is a perspective view of composite material 10. As shown in FIG. 1, composite material 10 is in a form of a plate. A thickness direction of composite material 10 is referred to as a “thickness direction.” Composite material 10 is provided with a first surface 10a and a second surface 10b. First surface 10a and second surface 10b form end surfaces of composite material 10 in the thickness direction. Second surface 10b is a surface opposite to first surface 10a.

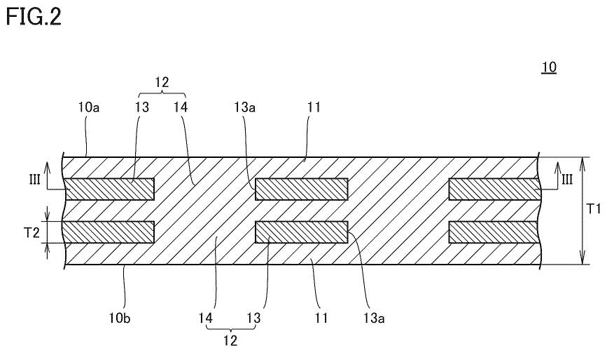

FIG. 2 is a cross-sectional view along II-II in FIG. 1. As shown in FIG. 2, composite material 10 is provided with a plurality of first layers 11 and at least one second layer 12. First layer 11 and second layer 12 are layered along the thickness direction such that first layer 11 is located at first surface 10a and second surface 10b. A thickness of composite material 10 is expressed as a thickness T1 and a thickness of second layer 12 is expressed as T2. Thickness T1 is preferably not larger than 1.5 mm. Thickness T2 is preferably not larger than 0.3 mm and further preferably not larger than 0.15 mm. A total of the number of first layers 11 and the number of second layers 12 is not smaller than three. The number of first layers 11 and the number of second layers 12 are preferably set to five.

First layer 11 is a layer of a metallic material mainly composed of copper. The “metallic material mainly composed of copper” means a metallic material in which a content of copper is not lower than 50 mass percent. First layer 11 is preferably a layer of a metallic material in which the content of copper is not lower than 70 mass percent. First layer 11 is, for example, a layer of pure copper. Pure copper refers to a metallic material composed of copper and a remainder composed of an inevitable impurity.

Second layer 12 includes a molybdenum plate 13 and a copper filler 14. Molybdenum plate 13 is a plate of a metallic material mainly composed of molybdenum. The “metallic material mainly composed of molybdenum” means a metallic material in which a content of molybdenum is not lower than 50 mass percent. Molybdenum plate 13 is preferably a plate of a metallic material in which the content of molybdenum is not lower than 70 mass percent. Molybdenum plate 13 is, for example, a plate of pure molybdenum. Pure molybdenum is a metallic material composed of molybdenum and a remainder composed of an inevitable impurity. Copper filler 14 is composed, for example, of a material identical to that for first layer 11.

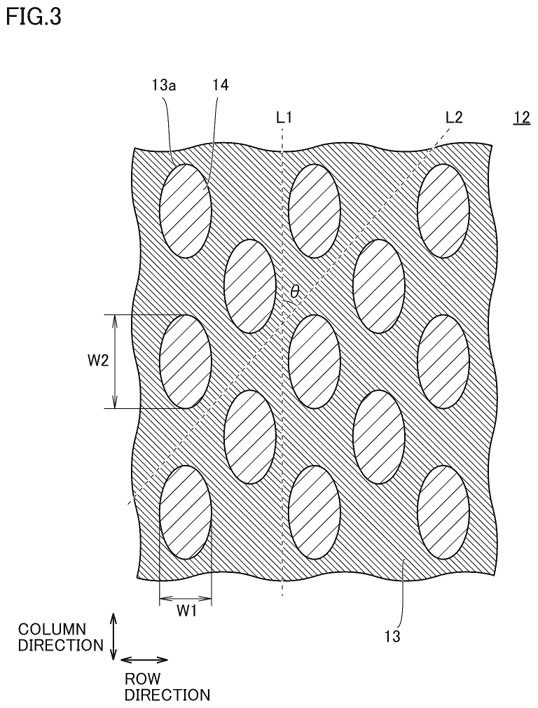

FIG. 3 is a cross-sectional view along III-III in FIG. 2. As shown in FIGS. 2 and 3, molybdenum plate 13 is provided with a plurality of openings 13a. Openings 13a pass through molybdenum plate 13 along the thickness direction. In a cross-sectional view orthogonal to the thickness direction, openings 13a are aligned in lattice arrangement. More specifically, in the cross-sectional view orthogonal to the thickness direction, openings 13a are aligned in staggered arrangement. In the cross-sectional view orthogonal to the thickness direction, openings 13a may be aligned in lattice of squares or lattice of quadrangles.

A row direction and a column direction of lattice arrangement of openings 13a are referred to as a “row direction” and a “column direction,” respectively. The column direction extends, for example, along a direction of rolling of composite material 10. The column direction is, for example, orthogonal to the row direction. A pitch between openings 13a adjacent in the row direction is referred to as a first pitch. A pitch between openings 13a adjacent in the column direction is referred to as a second pitch. The second pitch is preferably larger than the first pitch.

The first pitch and the second pitch are measured in a cross-section that passes through a center in the thickness direction of molybdenum plate 13 and is orthogonal to the thickness direction. The cross-section that passes through the center in the thickness direction of molybdenum plate 13 and is orthogonal to the thickness direction is exposed as below.

Firstly, composite material 10 is observed from a side surface with a digital microscope to measure a distance between first surface 10a and the center in the thickness direction of molybdenum plate 13. Secondly, a plane polishing machine or an automatic rotary polishing machine is used to polish composite material 10 from a side of first surface 10a. An amount of polishing at this time is set to be equal to the distance between first surface 10a and the center in the thickness direction of molybdenum plate 13 measured as above. The cross-section that passes through the center in the thickness direction of molybdenum plate 13 and is orthogonal to the thickness direction is exposed as set forth above.

The first pitch is obtained by measuring, for all openings 13a, a distance between centers of openings 13a adjacent in the row direction and dividing the total of measurement values by the number of openings 13a. Similarly, the second pitch is obtained by measuring, for all openings 13a, a distance between centers of openings 13a adjacent in the column direction and dividing the total of measurement values by the number of openings 13a. A digital microscope is used for measurement of the first pitch and the second pitch.

In the cross-sectional view orthogonal to the thickness direction, opening 13a has a first width W1 which is a width in the row direction and a second width W2 which is a width in the column direction. First width W1 and second width W2 are measured in the cross-section that passes through the center in the thickness direction of molybdenum plate 13 and is orthogonal to the thickness direction. First width W1 is obtained by measuring the width in the row direction of all openings 13a and dividing the total of measurement values by the number of openings 13a. Similarly, second width W2 is obtained by measuring the width in the column direction of all openings 13a and dividing measurement values by the number of openings 13a. First width W1 is larger than 350 μm. A value calculated by dividing second width W2 by first width W1 is not smaller than one and not larger than two. A digital microscope is used for measurement of first width W1 and second width W2.

In the cross-sectional view orthogonal to the thickness direction, opening 13a is, for example, in an elliptical shape. In an example where opening 13a is in the elliptical shape in the cross-sectional view orthogonal to the thickness direction, a major axis of the ellipse extends, for example, along the column direction. In the cross-sectional view orthogonal to the thickness direction, opening 13a may be circular. A cross-sectional shape of opening 13a is not limited as such.

The number of openings 13a per 1 mm² is, for example, smaller than three. The number of openings 13a per 1 mm² is preferably smaller than two. The number of openings 13a per 1 mm² is obtained by dividing the number of openings 13a present in the cross-section that passes through the center in the thickness direction of molybdenum plate 13 and is orthogonal to the thickness direction by an area (unit: mm²) of the cross-section.

An aperture ratio of molybdenum plate 13 is, for example, not lower than 20 percent. The aperture ratio of molybdenum plate 13 may be not lower than 30 percent or not lower than 35 percent. The aperture ratio of molybdenum plate 13 is, for example, not higher than 70 percent. The aperture ratio of molybdenum plate 13 may be not higher than 60 percent. The aperture ratio of molybdenum plate 13 is obtained by measuring a total opening area of openings 13a in the cross-section that passes through the center in the thickness direction of molybdenum plate 13 and is orthogonal to the thickness direction and dividing the total of measurement values by the area of the cross-section. A digital microscope is used for measurement of the opening area of openings 13a in the cross-section that passes through the center in the thickness direction of molybdenum plate 13 and is orthogonal to the thickness direction.

In the cross-sectional view orthogonal to the thickness direction, molybdenum plate 13 includes a portion that is continuous without interfering with openings 13a along a first direction and a portion that is continuous without interfering with openings 13a along a second direction. The first direction refers to a direction indicated by a straight line L1 in FIG. 3 and the second direction refers to a direction indicated by a straight line L2 in FIG. 3. The first direction and the second direction may be directions different from the column direction and the row direction. An angle formed between the first direction and the second direction is defined as an angle θ. Angle θ is an angle not larger than 90°, of angles at which straight line L1 and straight line L2 intersect with each other. Angle θ is not smaller than 47° and not larger than 90°. Angle θ is preferably not smaller than 47° and smaller than 90°. Angle θ is measured in the cross-section that passes through the center in the thickness direction of molybdenum plate 13 and is orthogonal to the thickness direction.

When there are three or more directions of portions of molybdenum plate 13 that are continuous without interfering with openings 13a, a direction smallest in angle θ is selected from among those three or more directions.

A thermal conductivity in the thickness direction of composite material 10 is preferably not lower than 270 W/m·K at room temperature. The thermal conductivity in the thickness direction of composite material 10 is preferably not lower than 300 W/m·K at room temperature. “Room temperature” means 27° C.

The thermal conductivity in the thickness direction of composite material 10 is measured with a laser flash method. In the laser flash method, LFA447 MicroFlash (manufactured by NETZSCH) is used to measure a thermal diffusion coefficient of composite material 10, and the thermal conductivity in the thickness direction of composite material 10 is calculated based on the thermal diffusion coefficient as well as a volume ratio and specific heat of each constituent material for composite material 10. In calculation of the thermal conductivity, specific heat of each constituent material is determined based on “Metals Data Book, 4th Edition” edited by the Japan Institute of Metals and Materials (2004, Maruzen Publishing Co., Ltd.). Prior to measurement of the thermal conductivity of composite material 10, the thermal conductivity of a pure copper sample identical in shape is measured under the same condition, and with the use of a result thereof as the reference, a result of measurement is corrected.

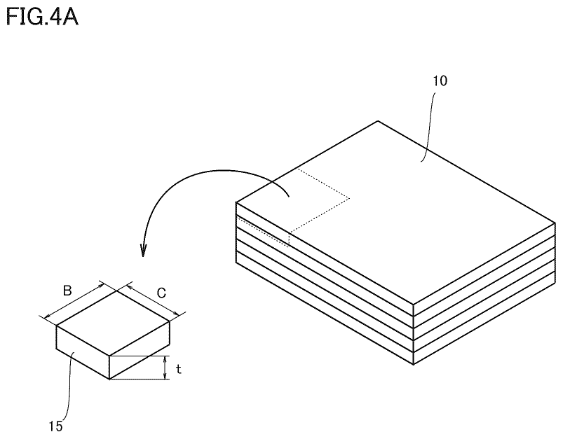

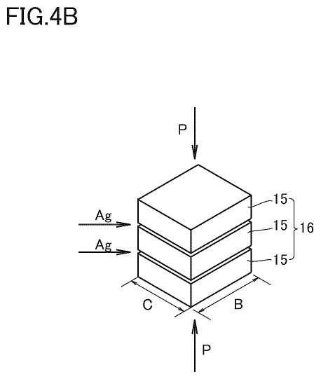

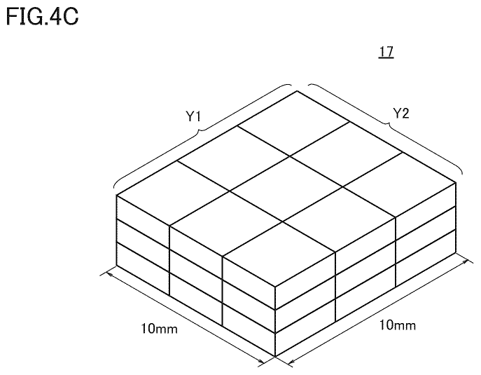

FIG. 4A is a first illustrative diagram of a procedure of making a measurement sample for measuring the thermal conductivity in the thickness direction of composite material 10. As shown in FIG. 4A, a thin piece 15 is cut from composite material 10 which is a target of measurement. A thickness, a length, and a width of thin piece 15 are t (mm), B (mm), and C (mm), respectively.

A number calculated by rounding up a value obtained by dividing two by t to a whole number is expressed as X. A number calculated by rounding up a value obtained by dividing ten by B to a whole number is expressed as Y1. A number calculated by rounding up a value obtained by dividing ten by C to a whole number is expressed as Y2. Thin pieces 15 in number equal to the product of X, Y1, and Y2 are cut from composite material 10 which is the target of measurement.

FIG. 4B is a second illustrative diagram of the procedure of making the measurement sample for measuring the thermal conductivity in the thickness direction of composite material 10. As shown in FIG. 4B, a block 16 is made from X thin pieces 15. A thickness, a length, and a width of block 16 are approximately 2 (mm), B (mm), and C (mm), respectively. In making block 16, firstly, X thin pieces 15 are stacked. At this time, amorphous powders formed of pure silver having an average particle size of 4 μm are arranged between adjacent thin pieces 15. An amount of amorphous powders arranged between adjacent thin pieces 15 is 0.2 g±30 percent per 100 mm².

In making block 16, secondly, a rectangular mold (not shown) provided with an opening having an inner dimension of B (mm)×C (mm) is prepared, and stacked thin pieces 15 are arranged in the opening. The mold is made of graphite. In making block 16, thirdly, stacked thin pieces 15 are thermally treated with a load P being applied thereto. Load P is not lower than 4.9 N and not higher than 9.8 N. Heat treatment is performed in an inert gas atmosphere. Heat treatment is performed at a retention temperature of 900° C. for a retention time period of ten minutes. As a result of heat treatment, amorphous powders are softened to deform, and adjacent thin pieces 15 are bonded to each other. Block 16 is thus made.

FIG. 4C is a third illustrative diagram of the procedure of making the measurement sample for measuring the thermal conductivity in the thickness direction of composite material 10. As shown in FIG. 4C, by aligning Y1 blocks 16 in a longitudinal direction and Y2 blocks 16 in a lateral direction, a measurement sample 17 having a height of approximately 10 mm, a width of approximately 10 mm, and a thickness of approximately 2 mm is made. In aligning Y1 blocks in the longitudinal direction and Y2 blocks in the lateral direction, adjacent blocks 16 are bonded to each other by an adhesive member. An adhesive member which can withstand a temperature up to approximately 800° C. such as a silver brazed foil or a ceramic adhesive is employed as the adhesive member. Y1 blocks 16 aligned in the longitudinal direction and Y2 blocks 16 aligned in the lateral direction may be fixed by being wound by a stainless wire or the like around an outer periphery thereof.

A coefficient of linear expansion (a first coefficient of linear expansion) of composite material 10 in the row direction in change in temperature from room temperature to 800° C. and a coefficient of linear expansion (second coefficient of linear expansion) of composite material 10 in the column direction in change in temperature from room temperature to 800° C. are preferably not larger than 14 ppm/K. The first coefficient of linear expansion and the second coefficient of linear expansion are further preferably not larger than 10 ppm/K. A value calculated by dividing the first coefficient of linear expansion by the second coefficient of linear expansion is not larger than 1.5.

The first coefficient of linear expansion and the second coefficient of linear expansion are calculated by measuring with TD5000SA (manufactured by Bruker AXS), displacement in the row direction and the column direction of composite material 10 in a temperature range from room temperature to 800° C. In calculation of the first coefficient of linear expansion and the second coefficient of linear expansion, a planar shape of composite material 10 is a rectangular shape of 3 mm×15 mm. A measurement value is an average value for three samples.

A volume ratio of molybdenum in composite material 10 is, for example, not higher than 25 percent. From a point of view of increase in thermal conductivity in the thickness direction of composite material 10, the volume ratio of molybdenum in composite material 10 is preferably not lower than 15 percent. From a point of view of decrease in coefficient of linear expansion of composite material 10, on the other hand, the volume ratio of molybdenum in composite material 10 is preferably lower than 15 percent.

### (Method of Manufacturing Composite Material 10)

A method of manufacturing composite material 10 will be described below.

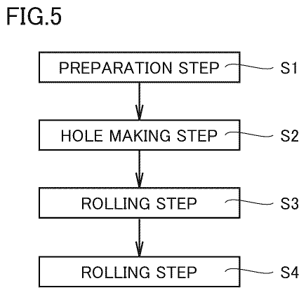

FIG. 5 is a diagram of a process for manufacturing composite material 10. As shown in FIG. 5, a method of manufacturing composite material 10 includes a preparation step S1, a hole making step S2, and a rolling step S3. In preparation step S1, a first plate material and a second plate material are prepared. The first plate material is a plate material made of a metallic material mainly composed of copper. The second plate material is a plate material made of a metallic material mainly composed of molybdenum.

In hole making step S2, a hole making work for the second plate material is performed. As a result of the hole making work, a plurality of openings that pass through the second plate material in the thickness direction are provided in the second plate material. Consequently, the second plate material becomes molybdenum plate 13. The hole making work for the second plate material is performed, for example, by etching or irradiation with laser.

In rolling step S3, firstly, a layered body 20 is prepared. Layered body 20 is prepared by alternately arranging the first plate material and molybdenum plate 13 along the thickness direction of layered body 20. In rolling step S3, secondly, heat treatment onto layered body 20 is performed. In this heat treatment, layered body 20 is heated to a prescribed temperature in a hydrogen atmosphere. This prescribed temperature is set to a temperature lower than a melting point of the first plate material, at which the first plate material is sufficiently softened. This prescribed temperature is set, for example, to 900° C.

In rolling step S3, thirdly, layered body 20 passes between reduction rollers. The first plate material and molybdenum plate 13 are thus joined to each other while they are rolled. At this time, as a result of flow of the first plate material, the first plate material is filled in openings 13a in molybdenum plate 13 to become copper filler 14. A remainder of the first plate material not filled in openings 13a becomes first layer 11. Composite material 10 in a structure shown in FIG. 2 is manufactured as set forth above. From another point of view, in composite material 10, first layer 11 and second layer 12 are joined with a hot roll bonding method.

The method of manufacturing composite material 10 may further include a rolling step S4. Rolling step S4 is performed after rolling step S3. In rolling step S4, thickness T1 is adjusted by cold rolling of composite material 10.

### (Construction of Semiconductor Package 100)

A construction of a semiconductor package 100 will be described below.

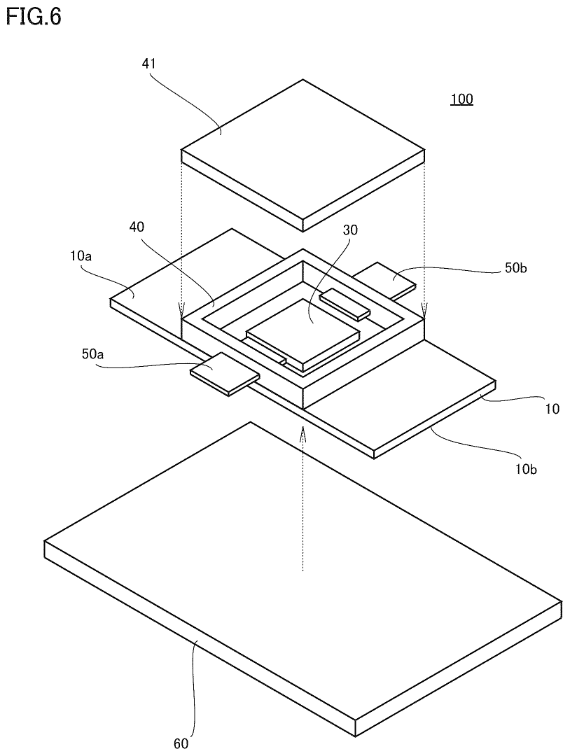

FIG. 6 is an exploded perspective view of semiconductor package 100. Semiconductor package 100 includes composite material 10, a semiconductor element 30, a case member 40, a lid 41, and a terminal 50a and a terminal 50b as shown in FIG. 6.

Composite material 10 functions as a heat spreader in semiconductor package 100. Semiconductor element 30 is arranged on first surface 10a. A heat transfer member may be interposed between semiconductor element 30 and first surface 10a. Semiconductor element 30 becomes a heat generation source during operation.

Case member 40 is made, for example, of a ceramic material. The ceramic material is, for example, alumina (Al₂O₃). Case member 40 is arranged on first surface 10a as surrounding semiconductor element 30. A lower end of case member 40 (an end on a side of first surface 10a) and first surface 10a are joined, for example, by brazing. Lid 41 is made, for example, of a ceramic material or a metallic material. Lid 41 closes an upper end side of case member 40.

Terminal 50a and terminal 50b are inserted in case member 40. Consequently, one ends of terminal 50a and terminal 50b are located in a space delimited by first surface 10a, case member 40, and lid 41 and the other ends of terminal 50a and terminal 50b are located on the outside of the space. Terminal 50a and terminal 50a are made, for example, of a metallic material. The metallic material is, for example, Kovar.

Though not shown, one end sides of terminal 50a and terminal 50b are electrically connected to semiconductor element 30. Semiconductor package 100 is electrically connected to an apparatus or a circuit different from semiconductor package 100 on the other end sides of terminal 50a and terminal 50b.

A heat radiation member 60 is attached to second surface 10b. Heat radiation member 60 is, for example, a metallic plate in which a flow channel through which refrigerant flows is provided. Heat radiation member 60 is not limited as such. Heat radiation member 60 may be, for example, a cooling fin. A heat transfer member may be interposed between heat radiation member 60 and second surface 10b.

### (Effect of Composite Material 10)

An effect of composite material 10 will be described below.

As set forth above, case member 40 is joined to composite material 10 with brazing or the like. Therefore, in order to lessen thermal stress caused by a difference between the coefficient of linear expansion of composite material 10 and the coefficient of linear expansion of case member 40, the coefficient of linear expansion of composite material 10 and the coefficient of linear expansion of case member 40 are preferably close to each other.

In an example where the coefficient of linear expansion of composite material 10 has anisotropy, even when the coefficient of linear expansion of composite material 10 in one direction (for example, the column direction) is close to the coefficient of linear expansion of case member 40, a difference between the coefficient of linear expansion of composite material 10 in another direction (for example, the row direction) and the coefficient of linear expansion of case member 40 is disadvantageously large.

Since the coefficient of linear expansion of molybdenum is smaller than the coefficient of linear expansion of copper, in a direction of extension of the portion of molybdenum plate 13 which is continuous without interfering with openings 13a, the coefficient of linear expansion of composite material 10 tends to be small. Therefore, as angle θ is larger, anisotropy of the coefficient of linear expansion of composite material 10 is less. As angle θ is smaller, on the other hand, a distance between adjacent openings 13a is longer and fracture of molybdenum plate 13 tends to occur between adjacent openings 13a at the time of rolling.

In an example where first width W1 is increased (specifically, exceeding 350 μm) and the value calculated by dividing second width W2 by first width W1 is not smaller than one and not larger than two, heat generated in semiconductor element 30 which is the heat generation source tends to conduct through copper filler 14 in conduction through second layer 12, and hence a thermal resistance of second layer 12 lowers. In this case, however, the distance between adjacent openings 13a is short and hence fracture of molybdenum plate 13 tends to occur between adjacent openings 13a at the time of rolling.

It was found as a result of dedicated studies by the present inventors that, in an example where angle θ was not smaller than 47° and not larger than 90°, even when first width W1 was larger than 350 μm and the value calculated by dividing second width W2 by first width W1 was not smaller than one and not larger than two, anisotropy of the coefficient of linear expansion of composite material 10 could be lessened while fracture of molybdenum plate 13 between adjacent openings 13a was suppressed.

### Example

Sample 1 to sample 7 were prepared as samples of the composite material. As shown in Table 1, sample 1 to sample 7 were varied in angle θ, first width W1, second width W2, the first pitch, the second pitch, the number of openings 13a per 1 mm², and the aperture ratio of molybdenum plate 13. In sample 1 to sample 7, first layer 11 was a layer of pure copper and molybdenum plate 13 was a plate of pure molybdenum. In sample 1 to sample 7, the number of first layers 11 was set to three and the number of second layers 12 was set to two.

As shown in Table 2, in sample 1 to sample 7, thickness T1 and the volume ratio of molybdenum were adjusted by adjusting the thickness of the first plate material and the thickness of molybdenum plate 13 yet to be rolled and adjusting a rolling reduction at the time of rolling. The rolling reduction at the time of rolling was adjusted as appropriate so as to prevent internal fracture of a material. The thickness of the first plate material shown in Table 2 is the thickness of the first plate material located at an outermost surface of layered body 20.

TABLE 1

| | | First | Second | Second | | | The Number | Aperture Ratio of |
|---|---|---|---|---|---|---|---|---|
| | Angle | Width | Width | Width | First | Second | of Openings | Molybdenum |
| | θ | W1 | W2 | W2 + First | Pitch | Pitch | 13a per 1 | Plate 13 |
| | (°) | (μm) | (μm) | Width W1 | (μm) | (μm) | mm2 | (%) |
| Sample 1 | 90 | 923 | 926 | 1.00 | 1287 | 1176 | 0.7 | 44 |
| Sample 2 | 49 | 869 | 1246 | 1.43 | 1057 | 1833 | 0.5 | 44 |
| Sample 3 | 55 | 394 | 493 | 1.25 | 518 | 748 | 2.6 | 39 |
| Sample 4 | 80 | 644 | 787 | 1.22 | 552 | 1343 | 1.3 | 54 |
| Sample 5 | 46 | 360 | 743 | 2.06 | 527 | 1043 | 1.8 | 38 |
| Sample 6 | 46 | 349 | 694 | 1.99 | 517 | 930 | 2.1 | 40 |
| Sample 7 | 26 | 451 | 1287 | 2.85 | 467 | 1783 | 1.2 | 55 |

TABLE 2

| | Thickness of | Thickness of | | |
|---|---|---|---|---|
| | First Plate | Molybdenum Plate 13 | Volume | Thick- |
| | Material | Yet to Be Rolled | Ratio of Mo | ness T1 |
| | (mm) | (mm) | (%) | (mm) |
| Sample 1 | 3 | 0.3 | 21.3 | 1.0 |
| Sample 2 | 3 | 0.3 | 22.3 | 1.0 |
| Sample 3 | 4 | 0.2 | 13.2 | 1.5 |
| Sample 4 | 4 | 0.2 | 12.8 | 1.0 |
| Sample 5 | 4 | 0.2 | 13.2 | 1.1 |
| Sample 6 | 4 | 0.2 | 13.2 | 1.2 |
| Sample 7 | 4 | 0.2 | 12.8 | 1.0 |

Angle θ being not smaller than 47° and not larger than 90° is defined as a condition A. First width W1 being not smaller than 350 μm is defined as a condition B. The value calculated by dividing second width W2 by first width W1 being not smaller than one and not larger than two is defined as a condition C. Sample 1 to sample 4 satisfied all of condition A to condition C. Sample 5 to sample 7, on the other hand, failed to satisfy at least one of condition A to condition C.

The first coefficient of linear expansion, the second coefficient of linear expansion, and the thermal conductivity in the thickness direction of sample 1 to sample 7 were measured. As shown in Table 3, in sample 1 to sample 4, a value calculated by dividing the first coefficient of linear expansion by the second coefficient of linear expansion was not larger than 1.5. In sample 5 to sample 7, on the other hand, the value calculated by dividing the first coefficient of linear expansion by the second coefficient of linear expansion was larger than 1.5.

TABLE 3

| | First | Second | First Coefficient | Thermal |
|---|---|---|---|---|
| | Coefficient | Coefficient | of Linear | Conductivity |
| | of Linear | of Linear | Expansion + Second | in Thickness |
| | Expansion | Expansion | Coefficient of Linear | Direction |
| | (ppm) | (ppm) | Expansion | (W/m·K) |
| Sample 1 | 7.18 | 7.46 | 1.0 | 291 |
| Sample 2 | 7.84 | 6.52 | 1.2 | 289 |
| Sample 3 | 11.73 | 9.17 | 1.3 | 332 |
| Sample 4 | 12.44 | 9.72 | 1.3 | 311 |
| Sample 5 | 14.66 | 7.55 | 1.9 | 327 |
| Sample 6 | 14.72 | 8.19 | 1.8 | 332 |
| Sample 7 | 18.56 | 9.78 | 1.9 | 316 |

It was experimentally clarified from this comparison that anisotropy of the coefficient of linear expansion of composite material 10 could be lessened by satisfying all of condition A to condition C. Though both of the first coefficient of linear expansion and the second coefficient of linear expansion in sample 1 to sample 4 were not larger than 14 ppm, the first coefficient of linear expansion was larger than 14 ppm in sample 5 to sample 7.

The volume ratio of molybdenum was lower than 15 percent in sample 1 and sample 2, whereas the volume ratio of molybdenum was not lower than 15 percent in sample 3 and sample 4. In sample 1 and sample 2, both of the first coefficient of linear expansion and the second coefficient of linear expansion were not larger than 10 ppm. In sample 3 and sample 4, the first coefficient of linear expansion was larger than 10 ppm. Though the thermal conductivity in the thickness direction was not lower than 270 W/m·K in sample 1 and sample 2, it was lower than 300 W/m·K. In sample 3 and sample 4, the thermal conductivity in the thickness direction was not lower than 300 W/m·K.

It was experimentally clarified from this comparison that the coefficient of linear expansion of composite material 10 could be made smaller by setting the volume ratio of molybdenum to be lower than 15 percent and that the thermal conductivity of composite material 10 could be lowered by setting the volume ratio of molybdenum to 15 percent or higher.

It should be understood that the embodiment disclosed herein is illustrative and non-restrictive in every respect. The scope of the present invention is defined by the terms of the claims rather than the embodiment above and is intended to include any modifications within the scope and meaning equivalent to the terms of the claims.

### REFERENCE SIGNS LIST

10a first surface; 10b second surface; 11 first layer; 12 second layer; 13 molybdenum plate; 13a opening; 14 copper filler; 15 thin piece; 16 block; 17 measurement sample; 20 layered body; 30 semiconductor element; 40 case member; 41 lid; 50a, 50b terminal; 60 heat radiation member; 10 composite material; 100 semiconductor package; S1 preparation step; S2 hole making step; S3, S4 rolling step; T1, T2 thickness; L1, L2 straight line; P load; W1 first width; W2 second width.

1. A composite material in a form of a plate provided with a first surface and a second surface, the second surface being a surface opposite to the first surface, the composite material comprising:
a plurality of first layers; and
at least one second layer, wherein
the first surface and the second surface form end surfaces in a thickness direction of the composite material,
the first layer and the second layer are alternately layered along the thickness direction such that the first layer is located at the first surface and the second surface,
the first layer is a layer of a metallic material mainly composed of copper,
the second layer includes a molybdenum plate and a copper filler,
the molybdenum plate is provided with a plurality of openings that pass through the molybdenum plate along the thickness direction,
the copper filler is arranged in inside of the openings,
in a cross-sectional view orthogonal to the thickness direction, the openings are aligned in lattice arrangement,
in the cross-sectional view orthogonal to the thickness direction, the openings each have a first width in a row direction of the lattice arrangement and a second width in a column direction of the lattice arrangement orthogonal to the row direction,
the first width is larger than 350 μm,
a value calculated by dividing the second width by the first width is not smaller than one and not larger than two,
in the cross-sectional view orthogonal to the thickness direction, the molybdenum plate includes a portion that is continuous without interfering with the openings along a first direction and a portion that is continuous without interfering with the openings along a second direction different from the first direction, and
an angle formed between the first direction and the second direction is not smaller than 47° and not larger than 90°.

2. The composite material according to claim 1, wherein
the angle formed between the first direction and the second direction is smaller than 90°.

3. The composite material according to claim 1, wherein
in the cross-sectional view orthogonal to the thickness direction, the number of the openings per 1 mm² is smaller than three.

4. The composite material according to claim 1, wherein
in the cross-sectional view orthogonal to the thickness direction, the number of the openings per 1 mm² is smaller than two.

5. The composite material according to claim 1, wherein
in the cross-sectional view orthogonal to the thickness direction, an aperture ratio of the molybdenum plate is not lower than 20 percent.

6. The composite material according to claim 1, wherein
a volume ratio of molybdenum in the composite material is not higher than 25 percent.

7. The composite material according to claim 1, wherein
a volume ratio of molybdenum in the composite material is not lower than 15 percent.

8. The composite material according to claim 1, wherein
a volume ratio of molybdenum in the composite material is lower than 15 percent.

9. The composite material according to claim 1, wherein
a total of the number of first layers and the number of second layers is set to five,
the composite material has a thickness not larger than 1.5 mm, and
the second layer has a thickness not larger than 0.3 mm.

10. The composite material according toof claim 1, wherein
a value calculated by dividing a coefficient of linear expansion in the row direction in change of a temperature from room temperature to 800° C. by a coefficient of linear expansion in the column direction in change in temperature from room temperature to 800° C. is not larger than 1.5.

11. The composite material according to claim 1, wherein
a pitch between the openings adjacent in the column direction is larger than a pitch between the openings adjacent in the row direction.

12. A heat spreader comprising:
the composite material according to claim 1, wherein
the first surface forms a surface of contact with a heat generation source.

13. A semiconductor package comprising:
the composite material according to claim 1; and
a semiconductor element, the semiconductor element being arranged on the first surface.

14. The semiconductor package according to claim 13, further comprising a case member made of a ceramic material, wherein
the case member is arranged on the first surface as surrounding the semiconductor element.
